(19) United States
(12) Patent Application Publication
(10) Pub. No.: US 2006/0071328 A1
(43) Pub. Date: Apr. 6, 2006

(54) Semiconductor substrate structure

(75) Inventors: Bily Wang, Hsin Chu City (TW); Jonnie Chuang, Pan Chiao City (TW); Shih-Yu Wu, Pan Chiao City (TW)

Correspondence Address: TROXELL LAW OFFICE PLLC, SUITE 1404, 5205 LEESBURG PIKE, FALLS CHURCH, VA, 22041, US

(73) Assignee: HARVATEK CORPORATION

(21) Appl. No.: 11/240,405

(22) Filed: Oct. 3, 2005

(30) Foreign Application Priority Data
Oct. 5, 2004 (TW) 93215756

(51) Int. Cl. H01L 23/34

(52) U.S. Cl. 257/720

(57) ABSTRACT

A semiconductor substrate structure with a highly heat-conductive advantage increases packaging good rate and quality. Using semiconductor chip packaging, an electronic chip is easily made highly heat-conductive, and compared with the prior art, the present invention has superior good rate for substrate structure. The improved heat-conductive structure avoids the semiconductor chip overheating and affects the life of electronic device by directly connecting the chip to the heat-conductive base plate.

### BACKGROUND OF THE INVENTION

1. Field of the Invention

The present invention relates to a semiconductor substrate structure, and more particularly, to a semiconductor substrate structure with a highly heat-conductive advantage and increased packaging good rate and quality. Using semiconductor chip packaging, an electronic chip is easily made to be highly heat-conductive, and, compared with the prior art, the present invention provides a superior packaging structure for an LED.

2. Description of Related Art

Semiconductor substrates are used in the packaging industry, and more particularly, power consumption semiconductor packages, such as a power semiconductor, are used for power circuits, LED and light sensors. The packaging industry is gradually increasing in importance due to electronic products that are required to be light, thin, short, and small and have many functions. The packaging technique of LED or semiconductor packaging industry will find new ways of doing things from old theories, conforming to the Surface Mount Technology (SMT) scale of 2 and 4 feet hold of LED. The substrate will be quite important, especially when the feet hold have more and larger power consumption and are required to have better heat-conductive packaging in the packaging structure.

In a conventional electronic packaging technique, a semiconductor integrated circuit or LED is manufactured and then assembled with other electronic elements to become an electronic product for achieving a specific design function. The electronic packaging technique provides four main functions, which respectively are power distribution, signal distribution, heat dissipation, and protection and support, as applied to IC chip packaging and LED packaging.

Referring to FIGS. 1A-1C, a conventional semiconductor substrate structure 1a, copper foil surface 12a is mounted on metal bottom 16a with polypropylene (PP) glue. A semiconductor chip is placed in the chip-mounting area 18a, and connected by a bonding wire to a pad-bonding of copper foil surface 12a. The conventional semiconductor substrate structure 1a has a problem of heat-conduction and fabrication. For example, pp glue conducts heat poorly and makes the semiconductor chip overheat, and has a negative effect on rate and fabrication. The chip has a bad effect because the chip-mounting area 18a of center square area is a multi-layer structure for heat pressing.

### SUMMARY OF THE INVENTION

An objective of the present invention is to provide a simplified structure for a better, highly heat-conductive semiconductor substrate, appropriate for use in an LED, light sensor or power adjust semiconductor, that is easily fabricated, cheaper, and high in quality.

The present invention thus provides a copper foil and polymer material (such as resin) connection, a hollow for a semiconductor chip accommodation space (the hollow substituted for the foregoing center square area 18a and heat-conduction directly to metal base 16a) and a highly heat-conductive base plate, fabricated in a conventional packaging process.

In addition, the present invention provides a wire-bonding (or other metal wire) bare-chip packaging manner, packaging tape or photoelectric chip power semiconductor, and different embodiments.

The present invention provides a semiconductor substrate structure including a heat-conductive base plate, having a contact surface for a semiconductor chip; and a polymer and metal stacked plate, attached on the heat-conductive base plate, and having a hollow area and a pad-bonding area. The hollow area has a semiconductor chip accommodation space for receiving a semiconductor chip to connect on the contact surface for a semiconductor chip.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1A is a cross-sectional view of a semiconductor substrate structure of the prior art;

FIG. 1B is a top view of a semiconductor substrate structure of the prior art;

FIG. 1C is a perspective view of a semiconductor substrate structure of the prior art;

FIG. 2A is a cross-sectional view of a semiconductor substrate structure of the present invention;

FIG. 2B is a top view of a semiconductor substrate structure of the present invention; and

FIG. 2C is a perspective view of a semiconductor substrate structure of the present invention.

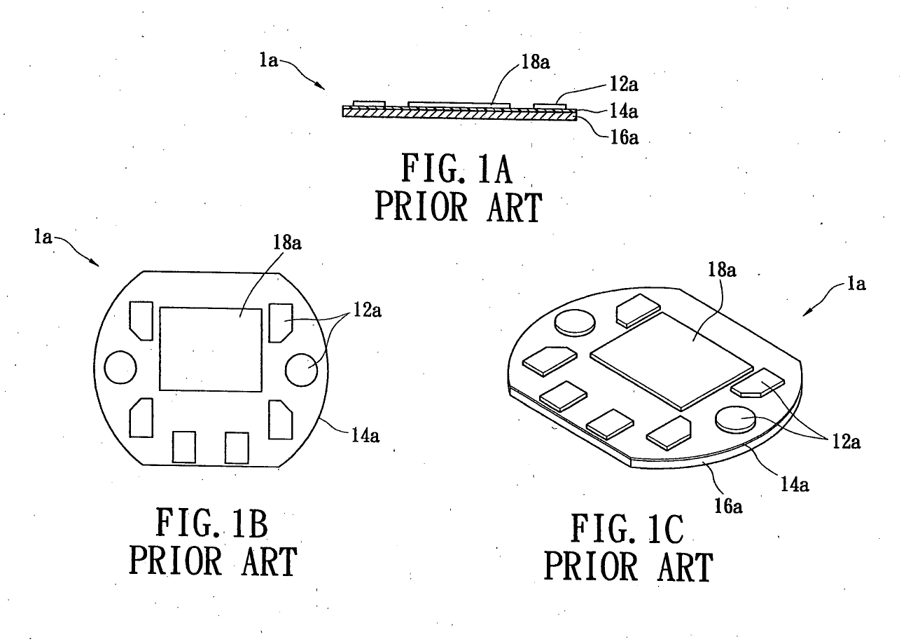

### DETAILED DESCRIPTION OF PREFERRED EMBODIMENTS

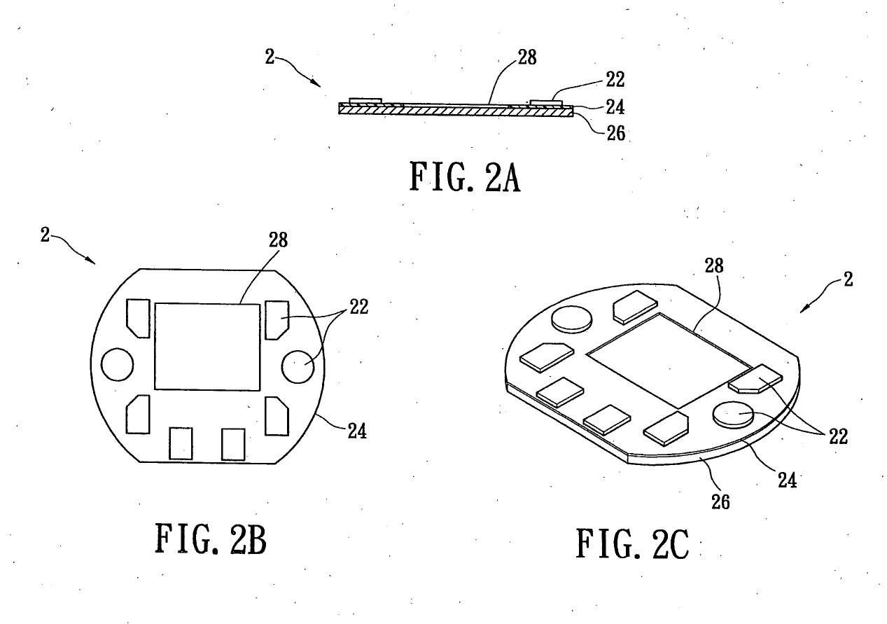

Referring to FIGS. 2A-2C, a semiconductor substrate structure 2 includes a polymer and metal stacked plate. The stack of polymer material 24 and copper plate 22 is formed by heat-pressing and etching, in a method similar to the printed circuit process. The stacked plate is cut with punching equipment such as a hole punch or punch cutter to form a semiconductor chip accommodation space 28, and connected by heat-pressing to a heat-conductive base plate 26 made of, for example, aluminum. The stacked plate (polymer and metal stacked plate) is the semiconductor substrate of present invention. The stacked plate includes a printed circuit; in the aforesaid, as a semiconductor chip and the present invention substrate is connected, and a semiconductor chip accommodation space 28 is attached to a bottom area of heat-conductive base plate 26 (the contact surface for a semiconductor chip) for rapid heat conduction. The present invention is highly heat-conductive, and the substrate (stacked plate, copper foil etching and cutting, and heat-pressed onto the heat-conductive base plate) and chip fabrication process (heat-pressing attached to chip) are simple, especially for a highly heat-conductive semiconductor device (such as an LED, a light sensor or a power semiconductor). The present invention heat-conductive base plate 26 is highly heat-conductive easily fabricated. In addition, the present invention provides a wire-bonding bare-chip packaging manner or an already-packaged scotch tape photoelectric chip or power semiconductor, and different embodiments.

Referring to FIGS. 2A-2C, a semiconductor substrate structure 2 includes a heat-conductive base plate 26 (aluminum plate or heat-conductive plate) with a contact surface for a semiconductor chip (accommodation semiconductor chip) and a polymer and metal stacked plate (formed by a method similar to the printed circuit process) attached on the heat-conductive base plate and having a hollow area and a pad-bonding area (for connecting to bonding wire of the semiconductor chip). The hollow area includes semiconductor chip accommodation space for receiving a semiconductor chip to connect on the contact surface for a semiconductor chip.

In addition, the present invention provides a semiconductor substrate structure including the polymer and metal stacked plate having a printed circuit connected to the pad-bonding area. The polymer and metal stacked plate includes a resistance or an inductance. The heat-conductive base plate is made of a metal or a heat-conductive polymer material. The heat-conductive base plate and the heat-conductive base plate have an alignment hole, an alignment edge or an alignment mark for attaching accurately. The polymer and metal stacked plate is a double-layer or multi-layer structure. The polymer and metal stacked plate is made of a stack of polymer plates and copper plates. The heat-conductive base plate is made of aluminum. The polymer plate is made of a phenolic aldehyde or an epoxide glass state cloth material. Phenolic aldehyde is made of phenolic aldehyde, epoxide, or polyester. The glass state cloth is made of epoxy resin (FR-4, FR-5), polyimide resin (PI), polyphenyl ether resin, polytetrafluorine resin, polytetrafluorine ethylene resin (PTFE), polycyanate ester, or polyolefin resin.

The present invention mainly features the forming of a hollow area from the semiconductor chip connected structure to conduct heat rapidly and the packaging structure is convenient because of the strong heat pressing. A lower equipment cost is incurred and does not affect the semiconductor chip packaging process. The semiconductor substrate structure of the present invention is a strong structure and easily fabricated. Further, the process method of the present invention will not affect the original substrate fabricating and packaging process, and it can be operated in the original substrate fabricating and packaging process due to the unchanged packaging machine to achieve the present requirement.

The present invention has following advantages: (1) highly heat-conductive; (2) convenient heat pressing fabrication; (3) the original packaging equipment is used; and (4) new manufacturing processes are easily arranged, so that the price and technique of new equipment is not high.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are embraced within the scope of the invention as defined in the appended claims.

What is claimed is:

1. A semiconductor substrate structure, comprising:
a heat-conductive base plate having a contact surface for a emiconductor chip; and
a polymer and metal stacked plate attached on the heat-conductive base plate, and having a hollow area and a pad-bonding area;
wherein the hollow area includes a semiconductor chip accommodation space for receiving a semiconductor chip to connect on the contact surface for a semiconductor chip.

2. The semiconductor substrate structure as claimed in claim 1, wherein the polymer and metal stacked plate includes a printed circuit connected to the pad-bonding area.

3. The semiconductor substrate structure as claimed in claim 1, wherein the polymer and metal stacked plate includes a resistance or an inductance.

4. The semiconductor substrate structure as claimed in claim 1, wherein the heat-conductive base plate is made of a metal or a heat-conductive polymer material.

5. The semiconductor substrate structure as claimed in claim 1, wherein the heat-conductive base plate and the polymer and metal stacked plate respectively have alignment holes, alignment edges or alignment marks for being accurately aligned to each other when attaching.

6. The semiconductor substrate structure as claimed in claim 1, wherein the polymer and metal stacked plate is a double-layer or a multi-layer structure.

7. The semiconductor substrate structure as claimed in claim 1, wherein the polymer and metal stacked plate is a stack of a polymer plate and a copper plate.

8. The semiconductor substrate structure as claimed in claim 4, wherein the heat-conductive base plate is made of aluminum.

9. The semiconductor substrate structure as claimed in claim 7, wherein the polymer plate is made of a phenolic aldehyde or a epoxide glass state cloth material and phenolic aldehyde is made of phenolic aldehyde, epoxide, or polyester, and wherein glass state cloth is made of epoxy resin (FR-4, FR-5), polyimide resin (PI), polyphenyl ether resin, polytetrafluorine resin, polytetrafluorine ethylene resin (PTFE), polycyanate ester, or polyolefin resin.
